(19) United States
(12) Patent Application Publication
(10) Pub. No.: US 2009/0026448 A1
(43) Pub. Date: Jan. 29, 2009

(54) ELECTRONIC COMPONENT, METHOD FOR ITS PRODUCTION AND ITS USE

(75) Inventors: Frank Meyer, Winchester (GB); Aurelie Ludemann, Frankfurt (DE); Rene Scheurich, Gross-Zimmern (DE); Heinrich Becker, Hofheim (DE); Klaus Meerholz, Roesrath (DE); David Christoph Mueller, Muenchen (DE); Nina Riegel, Donaustauf (DE); Anne Koehnen, Koeln (DE)

Correspondence Address: CONNOLLY BOVE LODGE & HUTZ, LLP, P O BOX 2207, WILMINGTON, DE, 19899, US

(73) Assignee: Merck Patent GmbH, Darmstadt (DE)

(21) Appl. No.: 12/279,113

(22) PCT Filed: Jan. 31, 2007
(86) PCT No.: PCT/EP07/00820

§ 371 Date: Aug. 12, 2008

(30) Foreign Application Priority Data
Feb. 13, 2006 (DE) 10 2006 006 412.7

(51) Int. Cl. H01L 51/00; H01L 51/40

(52) U.S. Cl. 257/40; 438/99; 257/E51.001

(57) ABSTRACT

The present invention relates to an electronic component having at least one anode, at least one cathode, at least one charge injection layer, at least one layer of an organic semiconductor and at least one layer situated between the charge injection layer and the organic semiconductor layer, which component is characterized in that the layer situated between the charge injection layer and the organic semiconductor layer and the organic semiconductor layer are obtainable by coating the charge injection layer with a mixture composing at least one material which can be made insoluble by means of chemical reaction, and at least one organic semiconductor, method for producing said component and use of said component.

Electronic devices which comprise organic, organometallic and/or polymeric semiconductors are being used ever more frequently in commercial products or are just about to be introduced onto the market. Examples which may be mentioned here are organic-based charge-transport materials (for example hole transporters based on triarylamine) in photocopiers and organic or polymeric light-emitting diodes (OLEDs or PLEDs) in display devices. Organic solar cells (O-SCs), organic field-effect transistors (O-FETs), organic thin-film transistors (O-TFTs), organic integrated circuits (O-ICs), organic optical amplifiers or organic laser diodes (O-lasers) are well advanced at a research stage and could achieve major importance in the future.

Many of these devices have, irrespective of the application, the following general layer structure, which is adapted correspondingly for the individual applications:
(1) substrate
(2) electrode, frequently metallic or inorganic, but also comprising organic or polymeric conductive materials
(3) optionally a charge-injection layer or interlayer for compensation of unevenness of the electrode (“planarisation layer”), frequently of a conductive, doped polymer
(4) organic semiconductor
(5) optionally insulation layer
(6) second electrode, materials as mentioned under (2)
(7) circuitry
(8) optionally encapsulation.

An advantage of many of these organic devices, especially those based on polymeric semiconductors, is that they can be produced from solution, which is associated with less technical complexity and expenditure of resources than vacuum processes, as generally carried out for low-molecular-weight compounds. For full-colour displays, the three primary colours (red, green, blue) must be applied alongside one another with high resolution in individual pixels (picture elements). An analogous situation applies to electronic circuits having different circuit elements. Whereas the individual pixels can be produced by vapour deposition of the individual colours through shadow masks in the case of low-molecular-weight, vapour-depositable molecules, this is not possible for polymeric materials and those processed from solution. One way out here consists in applying the active layer (for example the light-emitting layer in OLEDs/PLEDs; an analogous situation applies to charge-transport layers in all applications) directly in structured form. In particular, various printing techniques have recently been considered for this purpose, such as, for example, ink-jet printing (for example EP 0880303), offset printing and gravure coating. Intensive work is currently being carried out, in particular, on the development of ink-jet printing processes, and considerable advances have recently been achieved here, meaning that the first commercial products produced in this way can be expected soon.

In devices for organic electronics, an interlayer of a conductive, doped polymer which functions as charge-injection layer is frequently introduced between the electrode (in particular the anode) and the organic semiconductor (Appl. Phys. Lett 1997, 70, 2067-2069). The commonest of these polymers are polythiophene derivatives (for example poly(3,4-ethylene-dioxy-2,5-thiophene), PEDOT) and polyaniline (PANI), which are generally doped with polystyrenesulfonic acid or other polymer-bound Brönsted acids and thus converted into a conductive state. It is thought here that, during operation of the device, protons or other impurities diffuse out of the acidic groups into the functional layer, where they are suspected of having a significant adverse effect on the functionality of the device. Thus, it is thought that these impurities reduce the efficiency and also the lifetime of the devices.

More recent results (M. Leadbeater, N. Patel, B. Tierney, S. O'Connor, I. Grizzi, C. Towns, SID-Digest, p. 162, SID Seattle, 2004) show that the introduction of a hole-conducting buffer layer between the charge-injection layer of a conductive doped polymer and the organic semiconductor results in significantly improved device properties, in particular in a significantly increased lifetime. In practice, this buffer layer has hitherto generally been applied by an area-coating process and subsequently calcined. The material selected for the buffer layer will ideally have a glass transition temperature below that of the conductive doped polymer, and the calcination is carried out at a temperature above the glass transition temperature of the buffer layer, but below the glass transition temperature of the conductive doped polymer in order to avoid damaging the latter by the calcination operation. This generally renders a thin part of the buffer layer insoluble, generally in the order of 1 to 25 nm. For a relatively low glass transition temperature of the buffer layer, a material having a relatively low molecular weight is required. However, a material of this type cannot be applied by ink-jet printing since the molecular weight should be higher for good printing properties.

The soluble part of the buffer layer is then rinsed off by application of the organic semiconductor by spin coating, and the organic semiconductor layer is produced on the insoluble part of the buffer layer. Thus, a multilayered structure can be produced. However, it is not possible to apply the organic semiconductor to the buffer layer by a printing or coating process in this way since the solvent then partially dissolves the soluble part of the buffer layer, and an undefined blend of the material of the buffer layer and the organic semiconductor is formed. The production of structured multilayered devices is thus not possible in this way. The production of a device having a buffer layer solely by ink-jet printing has thus not been possible hitherto since, on the one hand, the buffer layer cannot be applied by printing techniques owing to the low molecular weight and since, on the other hand, the solution of the organic semiconductor partially dissolves the buffer layer during application by printing techniques. Since printing techniques, in particular ink-jet printing, are, however, regarded as a very important method for the production of structured devices, but on the other hand the use of buffer layers also has considerable potential for further developments, there is thus an even clearer need for improvement here.

EP 0637899 proposes electroluminescent arrangements having one or more layers in which at least one layer is crosslinked and which, in addition, contain at least one emitter layer and at least one charge-transport unit per layer. The crosslinking here can proceed by means of free radicals, anionically, cationically or via a photoinduced ring-closure reaction. Thus, a plurality of layers can be built up one above the other, and the layers can also be structured with radiation induction. However, no teaching is given regarding which of the variety of crosslinking reactions can produce a suitable device and how the crosslinking reaction is best carried out. It is merely mentioned that units which can be crosslinked by means of free radicals or groups which are capable of photocycloaddition are preferred, that assistants of various types, such as, for example, initiators, may be present, and that the film is preferably crosslinked by means of actinic radiation. Suitable device configurations are likewise not described. It is thus not clear how many layers the device preferably has, how thick these should be, which classes of material are preferably involved, and which thereof should be crosslinked. It is therefore also not evident to the person skilled in the art how the invention described can successfully be translated into practice.

ChemPhysChem 2000, 207 describes a triarylamine layer based on low-molecular-weight compounds which is crosslinked via oxetane groups as interlayer between a conductive doped polymer and an organic luminescent semiconductor. Higher efficiency is obtained here. A device of this type cannot be produced by printing processes, in particular ink-jet printing, since the low-molecular-weight triarylamine derivatives do not produce sufficiently viscous solutions before crosslinking.

WO 05/024971 describes that the electronic properties of the devices can be significantly improved if at least one crosslinkable polymeric buffer layer, preferably a cationically crosslinkable polymeric buffer layer, is introduced between the conducive doped polymer and the organic semiconductor layer. Particularly good properties are obtained in the case of a buffer layer whose crosslinking is thermally induced, i.e. by raising the temperature to 50 to 250° C. However, the crosslinking can also be initiated, for example, by irradiation with addition of a photoacid. In addition, a buffer layer of this type can also advantageously be applied by printing or coating techniques, in particular ink-jet printing, since the ideal temperature for the thermal treatment here is independent of the glass transition temperature of the material. There is thus no reliance on materials having a low molecular weight, which in turn facilitates the application of the layer by printing techniques. Since the crosslinking renders the buffer layer insoluble, the following layer (the organic semiconductor layer) can also be applied by various printing techniques, in particular ink-jet printing, since there is then no risk of partial dissolution of the buffer layer and blend formation. However, this procedure, in a similar manner to that described in M. Leadbeater, N. Patel, B. Tierney, S. O'Connor, 1. Grizzi, C. Towns, SID-Digest, p. 162, SID Seattle, 2004, has the considerable disadvantage that an additional layer has to be introduced between the charge-injection layer or interlayer and the organic semiconductor in the production of the electronic device, which means an additional working step. This results in greater technical complexity and expenditure of resources, which partially cancels out the original advantage of devices which can be processed from solution.

US 2005/0088079 describes a light-emitting device in which a light-emitting material has accumulated in one region and a polymer has accumulated in another region. The polymer here is prepared by selective cross-linking of a monomer comprising a mixture of the two materials, meaning that the light-emitting material accumulates in the first region and the polymer accumulates in the second region. According to the description, light-induced crosslinking results in a solid polymer in which light-emitting regions are embedded in the polymer (microcapsules). This process is initiated by a chemical reaction, in which the crosslinking described is initiated beyond the mixture in statistical terms. In this way, specific layering of separated layers one on top of the other cannot be achieved.

US 2005/0118457 discloses that an electronic device can be constructed by applying a blend of two materials having significantly different molecular weights to an electrode with the aid of a coating process and then directionally separating them parallel to the electrode surface. In this way, it is merely possible to form a multiplicity of layers by physical phase separation. As described in the specification, however, it is desired that this separation does not proceed to completion, but instead a transition zone of the blend remains.

Surprisingly, it has now been found that the electronic properties of the devices can be significantly improved without an additional layer having to be applied in a separate step by means of an area-coating process and without merely incomplete phase separation occurring if a solution which comprises at least two materials, at least one of which can be rendered insoluble via a chemical reaction, is applied to the charge-injection layer by a coating or printing process. Particularly good results are achieved here if the reaction of the reactive material, preferably a cationically crosslinkable material, is induced thermally, i.e. by raising the temperature to 50 to 250° C. It is thought that directional phase separation takes place during the chemical reaction, starting from the charge-injection layer, which results in the formation of a multilayered structure. This multilayered structure can be demonstrated by washing off the material that is not involved in the chemical reaction by means of the solvent employed previously, but is not restricted thereto. The washing-off of the material that is not involved in the reaction results in the formation of a very homogeneous surface of the crosslinked layer, which is significantly more homogeneous than that which can be achieved by the area-coating processes, in particular ink-jet printing, described in WO 05/024971.

In contrast to the process described in US 2005/0088079, the separation of the phases is carried out directionally, and the films formed can also be separated from one another again.

In contrast to US 2005/0118457, this separation of the phases is complete, which can be demonstrated by a layer-thickness measurement after the uncrosslinked layer has been washed off.

In this way, a defined multilayered structure can be built up by just one coating step. This is a clear technical advantage since comparably good or better properties are thus achieved than in the prior art with significantly less technical complexity.

Furthermore, the formation of the multilayered structure by the directional phase separation initiated by means of a chemical reaction results in a very homogeneous boundary layer between the two layers, which results in a significant reduction in interfacial defects, as can be observed in the case of separate layer build-up due to the formation of black spots and a large increase in voltage during operation.

The invention relates to an electronic component which has at least one anode, at least one cathode, at least one charge-injection layer, at least one layer of an organic semiconductor and at least one layer which is located between the charge-injection layer and the organic semiconductor layer, where the layer which is located between the charge-injection layer and the organic semiconductor layer and the organic semiconductor layer are obtainable by coating the charge-injection layer with a mixture comprising at least one material which can be rendered insoluble via a chemical reaction, and at least one organic semiconductor.

The chemical reaction which results in the formation of the insoluble material is preferably induced or initiated by the charge-injection layer. The chemical reaction starting produces complete and directional separation of the organic semiconductor. In a preferred embodiment, the material which can be rendered insoluble via a chemical reaction is also a correspondingly modified organic semiconductor. In a further preferred embodiment, the material which forms the charge-injection layer is suitable for initiation of a chemical reaction.

The present invention therefore furthermore relates to a process for the production of organic electronic devices which is characterised in that they contain at least one layer A which is suitable for initiation of a chemical reaction and at least one layer B of an organic semiconductor or conductor, characterised in that this layer B consists of at least two materials, at least one of which has the property of being rendered insoluble by a chemical reaction and separating from the other materials in the process and forming a separate layer on the initiating layer.

For the purposes of the present invention, insoluble is taken to mean that the chemical reaction of the material results in a layer which can no longer be dissolved to a significant extent by the solvent with which the material was originally applied.

The present invention furthermore relates to organic electronic devices which have been produced by the processes described above and are distinguished by improved interfacial properties.

For the purposes of this invention, directional separation of two or more components of a mixture is a process which begins in a defined manner at the surface of layer A and continues with any desired rate constant through the volume of the primary layer B lying on top. After completion of the separation, one component of the primary layer B has ideally accumulated completely at the surface of layer A and thus forms a further separate layer B1. The remaining components of the primary layer B form a third, separate layer B2 following layers A and B1.

The nature of the layer A initiating the chemical reaction is not restricted to conductive, doped, polymeric charge-injection layers, but also encompasses semiconducting and/or non-conducting layers of an inorganic or organic nature, merely characterised in that they are able to initiate the chemical reaction in layer B and the subsequent directional phase separation. The application of layer A to a substrate, which may already have been provided with further functional layers, can be carried out by means of any coating process familiar to the person skilled in the art. Mention may be made here by way of example, but without being restricted thereto, of coating processes from organic or non-organic solution, such as ink-jet printing, classical printing techniques, spin coating, dip coating or coating methods which use physical evaporation techniques in a high vacuum or in a stream of carrier gas.

In a particularly preferred embodiment, layer A consists of a conductive organic polymer, which is applied to a support from the liquid phase, preferably an aqueous phase. In this particularly preferred embodiment, the polymer is doped with an acid, preferably a polymeric acid, and this acid initiates the chemical reaction and the resultant directional separation of the materials in layer B.

In a very particularly preferred embodiment, layer A consists of polymers which, depending on the application, have a conductivity of >10⁻⁸ S/cm. Particular preference is given here to polymers having a conductivity of >10⁻⁶ S/cm and in particular having a conductivity >10⁻³ S/cm. The potential of the layer is preferably −4 to −6 eV against vacuum. The layer thickness is preferably between 10 and 500 nm, particularly preferably between 20 and 250 nm. Particular preference is given to the use of derivatives of polythiophene (in particular poly(3,4-ethylenedioxy-2,5-thiophene), PEDOT) and polyaniline (PANI). The doping is generally carried out by acids or by oxidants. The doping is preferably carried out by polymer-bound Brönsted acids. Particular preference is given for this purpose to polymer-bound sulfonic acids, in particular poly(styrenesulfonic acid), Nafion™, poly(vinylsulfonic acid) and PAMPSA (poly(2-acrylamido-2-methylpropanesulfonic acid)). The conductive polymer is generally applied from an aqueous solution or dispersion and is insoluble in organic solvents. The subsequent layer can thus easily be applied from organic solvents.

The composition of the layer B applied by a printing or coating method, preferably spin coating, dip coating, ink-jet printing or a conventional printing process, such as gravure, flexographic, offset or screen printing, can consist of soluble polymeric or soluble low-molecular-weight compounds or mixtures thereof, but at least of two components. Polymeric, oligomeric and high-molecular-weight compounds can have either a linear structure or be branched, highly branched or dendritic. The prerequisite is that at least one of the components is capable of a chemical reaction which results in directional separation of the layer. This component can either be a low-molecular-weight or a high-molecular-weight component. It is particularly preferred for the chemical reaction to be a crosslinking reaction which results in at least one of the directionally separated layers. Crosslinking reactions which can be used are in principle all chemical reactions which are suitable for this purpose, such as, for example, polymerisation reactions initiated by means of free radicals, anionically or cationically, metathesis or Diels-Alder reactions. Particular preference is given to cationic polymerisation, which can be initiated either photochemically, optionally with addition of an initiator (for example a photoacid), or thermally. Particular preference is given here to thermally initiated cationic polymerisation.

It is particularly preferred for the directional separation of the components of layer B produced by the chemical reaction to result in a layer structure where the layer B forming on the layer A initiating the chemical reaction can deal with the following, but not exclusively the following, functions, by way of example, for operation of the organic electronic device:
Mechanical blocking layer in order to slow or suppress migration of low-molecular-weight and/or polymeric materials from the charge-injection layer and/or the electrode into the luminous layer.
Electronic blocking layer in order to keep charges in the functional layer B of the organic electronic device or to slow the entry or transfer of electrons into layer A.
Light-emitting layer.

If the component of the organic semiconductor which is capable of chemical reaction is similar in its physical properties to the materials as in ChemPhys 2000, 207 or WO 05/024971 and M. Leadbeater, N. Patel, B. Tierney, S. O'Connor, I. Grizzi, C. Towns, SID Digest, SID Seattle, 2004, an organic electronic device which contains a hole-conducting layer which does not have to be applied in a separate area-coating step can then be produced. The buffer layer formed in this way results in a comparable improvement in the electronic properties of the device with significantly less technical complexity.

It is thought that the protons or other cationic impurities present in the conductive doped polymer are problematic and diffusion thereof out of the doped polymer is suspected of limiting the lifetime of the electronic device. In addition, hole injection from the doped polymers into the organic semiconductor is often unsatisfactory.

A buffer layer of this type offers a significant improvement here. The directional separation of the organic semiconductor by the reactive component therefore develops a polymeric layer, referred to as layer B1 below, between the conductive, doped polymer and the other components of the organic semiconductor. It is particularly advantageous for this layer B1 to contain crosslinked units, in particular cationically crosslinked units, so that it is able to take up low-molecular-weight, cationic species and intrinsic cationic charge carriers which are able to diffuse out of the conductive, doped polymer. However, other crosslinkable groups, for example groups which can be crosslinked anionically or by means of free radicals, are also possible and in accordance with the invention. This layer B1 may furthermore serve for improved hole injection and as electron-blocking layer, without being restricted to this function. For the directional separation for the formation of this layer B1, preference is given to the use of crosslinkable polymers, particularly preferably conjugated or partially conjugated crosslinkable polymers, in particular conjugated crosslinkable polymers. The molecular weight of the polymers used for layer B1 is preferably in the range from 50 to 500 kg/mol, particularly preferably in the range from 200 to 300 kg/mol, before crosslinking. This molecular-weight range has proven particularly suitable for application by ink-jet printing. For other printing techniques, however, other molecular-weight ranges may also be preferred. The layer thickness of the resultant layer B1 is preferably in the range from 1 to 300 nm, particularly preferably in the range from 10 to 200 nm, and in particular in the range from 15 to 100 nm. The desired layer thickness of layer B1 is set by means of the proportion of reactive chemical materials in layer B. It should be described by way of example here that, if layer B has a layer thickness of 100 nm before the chemical reaction and consists of 50% of materials which are capable of reaction, layer B1 formed from the directional separation has a layer thickness of about 50 nm.

The potential of layer B1 is preferably between the potential of the conductive, doped polymer and that of the organic semiconductor in order, if desired, to improve the charge injection. This can be achieved by a suitable choice of the materials for layer B1 and suitable substitution of the materials.

It may also be preferred to admix further crosslinkable low-molecular-weight compounds with the polymeric material which results in the formation of layer B1. This may be appropriate in order, for example, to reduce the glass transition temperature of the mixture and thus to facilitate crosslinking at lower temperature.

However, it may also be preferred for the materials which are capable of the formation of layer B1 to be built up exclusively from low-molecular-weight materials if the remaining components of layer B, if necessary, help to set the requisite physical parameters for the area-application method. Preferred materials for layer B1 are derived from hole-conducting materials. Particularly preferably suitable for this purpose are cationically cross-linkable materials based on triarylamine, on thiophene, on triarylphosphine or combinations of these systems, where copolymers thereof with other structures, for example fluorenes, spirobifluorenes, dihydrophenanthrenes, indenofluorenes and phenanthrenes, also represent suitable materials if a sufficiently high proportion of the hole-conducting units mentioned above is used. The proportion of hole-conducting units in the polymer is particularly preferably at least 10 mol %. It is particularly preferred for the proportion of hole-conducting units to be between 40 and 60 mol %. The potentials of these compounds can be adjusted through suitable substitution. Thus, the introduction of electron-withdrawing substituents (for example F, Cl, CN, etc.) gives compounds having a lower HOMO (=highest occupied molecular orbital), while electron-donating substituents (for example alkoxy groups, amino groups, etc.) produce a higher HOMO.

It is thought that a cationically crosslinkable layer B is able to take up diffusing cationic species, in particular protons. This initiates the crosslinking reaction. On the other hand, the crosslinking simultaneously forms a layer B1, which is insoluble, meaning that, after the soluble layer B2 has been washed away, application of a further organic semiconductor from the usual organic solvents subsequently presents no problems. The cross-linked layer B1 represents a further barrier against diffusion.

Preferred polymerisable groups are therefore cationically crosslinkable groups, in particular:
1) electron-rich olefin derivatives,
2) heteronuclear multiple bonds with heteroatoms or heterogroups, and
3) rings containing heteroatoms (for example O, S, N, P, Si, etc.) which react by cationic ring-opening polymerisation.

Electron-rich olefin derivatives and compounds containing heteronuclear multiple bonds with heteroatoms or heterogroups are preferably those as described in H.-G. Elias, Makromoleküle [Macromolecules], Volume 1. Grundlagen: Struktur—Synthese—Eigenschaften [Fundamentals: Structure—Synthesis—Properties], Hüthig & Wepf Verlag, Basle, 5th Edition, 1990, pp. 392-404, without wishing thereby to restrict the variety of possible compounds.

Preference is given to organic materials in which at least one H atom has been replaced by a group which reacts by cationic ring-opening polymerisation. A general review of cationic ring-opening polymerisation is given, for example, by E. J. Goethals et al., “Cationic Ring Opening Polymerisation” (New Methods Polym. Synth. 1992, 67-109). Generally suitable for this purpose are non-aromatic cyclic systems in which one or more ring atoms are, identically or differently, O, S, N, P, Si, etc. Preference is given here to cyclic systems having 3 to 7 ring atoms in which 1 to 3 ring atoms are, identically or differently, O, S or N. Examples of such systems are unsubstituted or substituted cyclic amines (for example aziridine, azeticine, tetrahydropyrrole, piperidine), cyclic ethers (for example oxirane, oxetane, tetrahydrofuran, pyran, dioxane), and also the corresponding sulfur derivatives, cyclic acetals (for example 1,3-dioxolane, 1,3-dioxepan, trioxane), lactones, cyclic carbonates, but also cyclic structures which contain different heteroatoms in the ring (or example oxazolines, dihydrooxazines, oxazolones). Preference is furthermore given to cyclic siloxanes having 4 to 8 ring atoms.

For the formation of layer B1, very particular preference is given to low-molecular-weight, oligomeric or polymeric organic materials in which at least one H atom has been replaced by a group of the formula (I), formula (II) or formula (III)

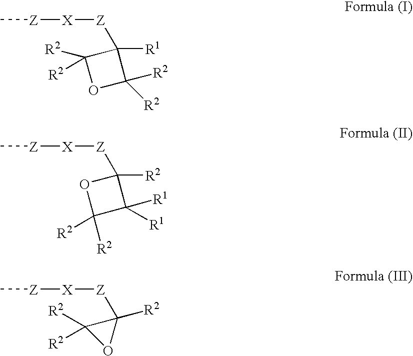

where:
R¹ is on each occurrence, identically or differently, hydrogen, a straight-chain, branched or cyclic alkyl, alkoxy or thioalkoxy group having 1 to 20 C atoms, an aromatic or heteroaromatic ring system having 4 to 24 aromatic ring atoms or an alkenyl group having 2 to 10 C atoms, in which one or more hydrogen atoms may be replaced by halogen, such as, for example, Cl and F, or CN, and one or more non-adjacent C atoms may be replaced by —O—, —S—, —CO—, —COO— or —O—CO—; a plurality of radicals R¹ here may also form a mono- or polycyclic, aliphatic or aromatic ring system with one another or with R², R³ and/or R⁴,
R² is on each occurrence, identically or differently, hydrogen, a straight-chain, branched or cyclic alkyl group having 1 to 20 C atoms, an aromatic or heteroaromatic ring system having 4 to 24 aromatic ring atoms or an alkenyl group having 2 to 10 C atoms, in which one or more hydrogen atoms may be replaced by halogen, such as, for example, Cl and F, or CN, and one or more non-adjacent C atoms may be replaced by —O—, —S—, —CO—, —COO— or —O—CO—; a plurality of radicals R² here may also form a mono- or polycyclic, aliphatic or aromatic ring system with one another or with R¹, R³ and/or R⁴,
X is on each occurrence, identically or differently, —O—, —S—, —CO—, —COO—, —O—CO— or a divalent group —(CR³R⁴)ₙ—,
Z is on each occurrence, identically or differently, a divalent group —(CR³R⁴)ₙ—,
R³, R⁴ is on each occurrence, identically or differently, hydrogen, a straight-chain, branched or cyclic alkyl, alkoxy, alkoxyalkyl or thioalkoxy group having 1 to 20 C atoms, an aromatic or heteroaromatic ring system having 4 to 24 aromatic ring atoms or an alkenyl group having 2 to 10 C atoms, in which one or more hydrogen atoms may also be replaced by halogen, such as, for example, Cl or F, or CN; two or more radicals R³ or R⁴ here may also form a ring system with one another or also with R¹ or R²,
n is on each occurrence, identically or differently, an integer between 0 and 20, preferably between 1 and 10 and particularly preferably between 1 and 6,
   with the proviso that the number of these groups of the formula (I) or formula (II) or formula (III) is limited by the maximum number of available, i.e. substitutable, H atoms.

The crosslinking of these units can be initiated, for example, by thermal treatment of the device. A photoacid for the crosslinking can optionally also be added. Preference is given to thermal crosslinking without addition of a photoacid. Further assistants may likewise optionally be added, such as, for example, salts or acids, which are added to the buffer layer and/or to the conductive polymer layer. This crosslinking is preferably carried out at a temperature of 80 to 200° C. and for a duration of 0.1 to 120 minutes in an inert atmosphere. This crosslinking is particularly preferably carried out at a temperature of 100 to 180° C. and for a duration of 30 to 120 minutes in an inert atmosphere.

If the component of the organic semiconductor which is capable of chemical reaction and directional separation is a light-emitting material in its physical properties, it is possible to produce a device which in principle allows multicoloured layer systems to be built up in a single process step. It is likewise possible to construct a device in which the component which is capable of chemical reaction and directional separation exerts a light-emitting function, while the other component is selected in its electronic properties so that it represents a barrier for holes in order to prevent losses of power at the cathode.

It is likewise possible to produce a device where a layer B2, without being restricted to just one layer, which, in its physical properties, represents a barrier layer for holes and electrons on the directionally separated layer B1.

In the planning of corresponding multilayered structures, the design principle always applies that the components of layer B which are chemically reactive always form a layer B1 following A on the layer A initiating the chemical reaction. The components which are not capable of the chemical reaction in the sense of the invention then form the third layer B2.

The said examples should only be regarded as illustrative in order to demonstrate the range of possibilities. The possibilities of construction of the organic electronic device that can be achieved are evident to the person skilled in the art.

Preferred materials for a structure of this type of layer B1 of an organic electronic device are cationically crosslinkable low-molecular-weight, oligomeric or polymeric organic materials in which at least one H atom has been replaced by a group of the formula (A)

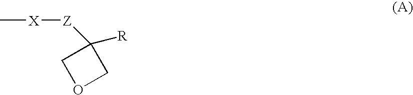

in which
R denotes a straight-chain, branched or cyclic alkyl, alkoxyalkyl, alkoxy or thioalkoxy group having 1 to 20 C atoms, C₄-C₁₈-aryl or C₂-C₁₀-alkenyl, in which one or more hydrogens may be replaced by halogen, such as, for example, Cl and F, or CN, and one or more non-adjacent C atoms may be replaced by —O—, —S—, —CO—, —COO— or —O—CO—,
Z stands for —O—, —S—, —CO—, —COO—, —O—CO— or a divalent group —(CR¹R²)ₙ—, in which R¹ and R², independently of one another, denote hydrogen, a straight-chain, branched or cyclic alkyl, alkoxy, alkoxyalkyl or thioalkoxy group having 1 to 20 C atoms, C₄-C₁₈-aryl, C₂-C₁₀-alkenyl, in which one or more hydrogens may be replaced by halogen, such as, for example, Cl and F, or CN, and one or more non-adjacent C atoms may be replaced by —O—, —S—, —CO—, —COO— or —O—CO—,
X stands for —O—, —S—, —CO—, —COO—, —O—CO— or a divalent group —(CR¹R²)ₙ—, in which R¹ and R², independently of one another, denote hydrogen, a straight-chain, branched or cyclic alkyl, alkoxy, alkoxyalkyl or thioalkoxy group having 1 to 20 C atoms, C₄-C₁₈-aryl, C₂-C₁₀-alkenyl, in which one or more hydrogens may be replaced by halogen, such as, for example, Cl and F, or CN, and
n denotes an integer between 1 and 20, preferably between 3 and 10, and particularly preferably 3 or 6,
   with the proviso that the number of these groups of the formula A is restricted by the maximum number of available, i.e. substitutable, H atoms.

The chemically reactive materials used in accordance with the invention are electroluminescent or laser materials, preferably
A) homo- or copolymers based on PPV or polyfluorenes or polyspiro or polydihydrophenanthrene or polyphenanthrene or polyindenofluorenes,
B) low-molecular-weight compounds having a 3-dimensional spirobifluorene structure,
C) low-molecular-weight compounds having a 3-dimensional triptycene structure,
D) low-molecular-weight compounds having a 2-dimensional triphenylene structure,
E) derivatives of perylenetetracarboxylic acid diimide,
F) derivatives of quinacridone,
G) organic lanthanoid complexes,
H) derivatives of aluminium trisquinoxalinate,
I) oxadiazole and triazine derivatives,
J) organometallic complexes which are capable of phosphorescence,
   hole-conductor materials, preferably
K) polystyrenes, polyacrylates, polyamides, polyesters, which carry derivatives of tetraarylbenzidine in the side chain,
L) low-molecular-weight compounds having a 2-dimensional triphenylene and triarylamine structure,
M) copolymers with triarylamines,
N) dendritic amines,
   or electron-conductor materials, preferably
O) derivatives of aluminium trisquinoxalinate,
P) oxadiazole and triazine derivatives.

However, it is also possible to employ reactive materials which produce a non-conducting layer B1 on layer A. This layer structure can be used in applications which are different from optical organic electronic devices, such as, for example, organic field-effect transistors (OFETs).

It is advantageous here that the directional separation of the materials in layer B is not tied to the sequence in which the layers are built up. Thus, layer A can be coated onto layer B. Through initiation of the chemical reaction, directional separation also occurs in this case, with the chemically reacting component in layer B separating in the direction of layer A applied above and forming a layer B1.

Thus, a non-conducting layer can be produced by two methods:
a) The non-conducting component in layer B is chemically reactive and thus forms a layer B1 after the chemical reaction. The non-reacting layer B2 can, depending on the sequence of the coatings of A and B, be on the side of layer A facing the substrate or facing away from the substrate.
b) The non-conducting component in layer B is chemically inactive and, after the chemical reaction, forms a layer B2 which results in the formation of layer B1. Depending on the sequence of the coatings of layers A and B, the non-conducting layer B2 can be on the side of layer A facing the substrate or facing away from the substrate.

The oxetane content is defined by the molar ratio of oxetane rings, based on the total number of organic rings, i.e. including the oxetane rings in the respective structure. This can generally be determined by analytical methods. One of the preferred methods, besides IR spectroscopy, is nuclear magnetic resonance (NMR) spectroscopy.

For the purposes of the invention, rings are cyclic structural elements formed from at least three ring atoms, with the proviso that at least two C atoms are present (The Ring Index, Patterson and Capell, Reinhold Publishing Company, 1940 and Handbook of Chemistry and Physics, 62^{nd} ed. 1981, C-48).

The oxetane content can be varied in broad ranges from 0.01 to 0.6. In the lower range, low degrees of crosslinking are achieved, giving relatively soft, rubbery to gelatinous layers. In the upper range, high crosslinking densities are achieved with thermoset-like properties, such as, for example, Bakelite.

A1) The homo- and copolymers of PPV contain one or more structural units of the formula (B), where at least one H atom in the polymer is replaced by a substituent of the formula (A) and/or of the formula (I), (II) and/or (III)

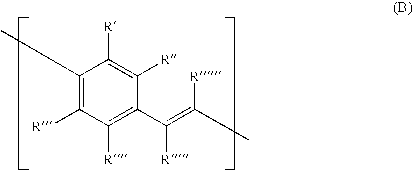

The substituents R′ to R″″″ here are, identically or differently, H, CN, F, Cl or a straight-chain, branched or cyclic alkyl or alkoxy group having 1 to 20 C atoms, where one or more non-adjacent CH₂ groups may be replaced by —O—, —S—, —CO—, —COO—, —O—CO—, —NR¹—, —(NR²R³)⁺-A⁻ or —CONR⁴— and where one or more H atoms may be replaced by F, or an aryl group having 4 to 14 C atoms, which may be substituted by one or more non-aromatic radicals R′,
R¹, R²,
R³, R⁴ are, identically or differently, aliphatic or aromatic hydrocarbon radicals having 1 to 20 C atoms or also H,
A⁻ is a singly charged anion or an equivalent thereof.

Preference is given here to PPVs in accordance with WO 98/27136, which are reproduced in formula (C)

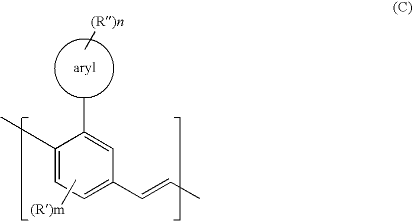

where the symbols and indices have the following meanings:
aryl is an aryl group having 4 to 14 C atoms,
R′, R″ are, identically or differently, a straight-chain, branched or cyclic alkyl or alkoxy group having 1 to 20 C atoms, where one or more non-adjacent CH₂ groups may be replaced by —O—, —S—, —CO—, —COO—, —O—CO—, —NR¹—, —(NR²R³)⁺-A⁻ or —CONR⁴— and where one or more H atoms may be replaced by F, or denote CN, F, Cl or an aryl group having 4 to 14 C atoms, which may be substituted by one or more non-aromatic radicals R′,
R¹, R²,
R³, R⁴ are, identically or differently, aliphatic or aromatic hydrocarbon radicals having 1 to 20 C atoms or also H,
A⁻ is a singly charged anion or an equivalent thereof
m is 0, 1 or 2,
n is 1, 2, 3, 4 or 5.

Particular preference is given to polymers consisting principally of recurring units of the formula (C).

Especial preference is furthermore also given to copolymers essentially consisting of, preferably consisting of, recurring units of the formula (I) and further recurring units, which preferably likewise contain poly(arylene-vinylene) structures, particularly preferably 2,5-dialkoxy-1,4-phenylene-vinylene structures, where the alkoxy groups are preferably straight-chain or branched and contain 1 to 22 C atoms.

For the purposes of the present invention, copolymers encompass random, alternating, regular and block-like structures.

Preference is likewise given to polymers containing recurring units of the formula (C), in which the symbols and indices have the following meanings:
aryl is phenyl, 1- or 2-naphthyl, 1-, 2- or 9-anthracenyl, 2-, 3- or 4-pyridinyl, 2-, 4- or 5-pyrimidinyl, 2-pyrazinyl, 3- or 4-pyridazinyl, 2-, 3-, 4-, 5-, 6-, 7- or 8-quinoline, 2- or 3-thiophenyl, 2- or 3-pyrrolyl, 2- or 3-furanyl or 2-(1,3,4-oxadiazol)yl,
R′ is, identically or differently, CN, F, Cl, CF₃ or a straight-chain or branched alkoxy group having 1 to 12 C atoms,
R″ is, identically or differently, a straight-chain or branched alkyl or alkoxy group having 1 to 12 C atoms,
n is 0, 1, 2 or 3, preferably 0, 1 or 2.

The preparation of polymers of this type is described in detail in WO 98/27136. The preparation of corresponding polymers according to the invention can be carried out by copolymerisation of corresponding monomers which carry the substituents of the formula (A) and/or of the formula (I), (II) and/or (III).

A2) The homo- and copolymers of polyfluorene contain one or more structural units of the formula (D), where at least one H atom in the polymer has been replaced by a substituent of the formula (A) and/or of the formula (I), (II) and/or (III)

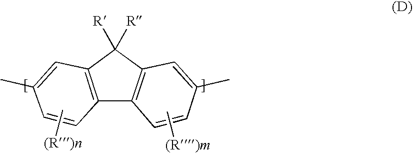

The substituents R′ to R″″ here are, identically or differently, H, CN, F, Cl or a straight-chain, branched or cyclic alkyl or alkoxy group having 1 to 20 C atoms, where one or more non-adjacent CH₂ groups may be replaced by —O—, —S—, —CO—, —COO—, —O—CO—, —NR¹—, —(NR²R³)⁺-A⁻ or —CONR⁴— and where one or more H atoms may be replaced by F, or an aryl group having 4 to 14 C atoms, which may be substituted by one or more non-aromatic radicals R′,
R¹, R²,
R³, R⁴ are, identically or differently, aliphatic or aromatic hydrocarbon radicals having 1 to 20 C atoms or also H,
A⁻ is a singly charged anion or an equivalent thereof,
n, m are, identically or differently, 0, 1, 2 or 3, preferably 0 or 1.

A2.1) Preference is given here to structures in accordance with DE-A-19846767, which are shown below. Besides structural units of the formula (E1)

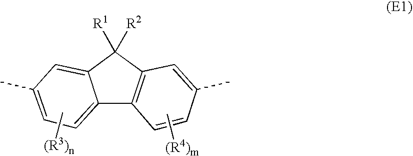

in which
R¹, R² denote, identically or differently, H, C₁-C₂₂-alkyl, C₂-C₂₀-heteroaryl, C₅-C₂₀-aryl, F, Cl or CN, where the alkyl radicals mentioned above may be branched or unbranched or also represent cyclo-alkyls, and individual, non-adjacent CH₂ groups of the alkyl radical may be replaced by O, S, C═O, COO, N—R⁵ or also C₂-C₁₀-aryl or heteroaryl radicals, where the aryl/heteroaryl radicals mentioned above may be substituted by one or more non-aromatic substituents R³. Preference is given to compounds in which R¹ and R² are both identical and are not equal to hydrogen or chlorine; preference is furthermore given to compounds in which R¹ and R² are different from one another and are also different from hydrogen,
R³, R⁴ denote, identically or differently, H, C₁-C₂₂-alkyl, C₂-C₂₀-heteroaryl, C₅-C₂₀-aryl, F, Cl, CN, SO₃R⁵ or NR⁵R⁶; the alkyl radicals here may be branched or unbranched or also represent cycloalkyl radicals; and individual, non-adjacent CH₂ groups of the alkyl radical may be replaced by O, S, C═O, COO, N—R⁵ or C₂-C₁₀-aryl or heteroaryl radicals, where the aryl/heteroaryl radicals mentioned above may be substituted by one or more non-aromatic substituents R³,
R⁵, R⁶ denote, identically or differently, H, C₁-C₂₂-alkyl, C₂-C₂₀-hetero-aryl or C₅-C₂₀-aryl; the alkyl radicals here may be branched or unbranched or also represent cycloalkyls; and individual, non-adjacent CH₂ groups of the alkyl radical may be replaced by O, S, C═O, COO, N—R⁵ or also C₂-C₁₀-aryl radicals, where the aryl radicals mentioned above may be substituted by one or more non-aromatic substituents R³, and
m, n are, identically or differently, each an integer 0, 1, 2 or 3, preferably 0 or 1,
   these polymers also contain structural units of the formula (E2)

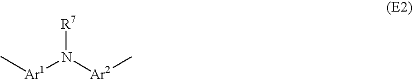

in which
Ar¹, Ar² are mono- or polycyclic aromatic conjugated systems having 2 to 40 carbon atoms, in which one or more carbon atoms may be replaced by nitrogen, oxygen or sulfur and which may be substituted by one or more substituents R³. It is entirely possible or in some cases even preferred here for the aromatic radicals Ar¹ and Ar² to be linked to one another by a bond or a further substituted or unsubstituted C atom or heteroatom and thus to form a common ring, and
R⁷ denotes, identically or differently, C₁-C₂₂-alkyl, C₂-C₂₀-heteroaryl or C₅-C₂₀-aryl; the alkyl radicals here may be branched or unbranched or also represent cycloalkyls; and individual, non-adjacent CH₂ groups of the alkyl radical may be replaced by O, S, C═O, COO, N—R⁵ or also simple aryl radicals, where the aryl/heteroaryl radicals mentioned above may be substituted by one or more non-aromatic substituents R³.

The structural units of the formula (E2) are very particularly preferably derived from the following parent structures:
diphenylamine derivatives, which are incorporated into the polymer in the 4,4′-position,
phenothiazine or phenoxazine derivatives, which are incorporated into the polymer in the 3,7-position,
carbazole derivatives, which are incorporated into the polymer in the 3,6-position,
dihydrophenazine derivatives, which are incorporated into the polymer in the 2,6- or 2,7-position, dihydroacridine derivatives, which are incorporated into the polymer in the 3,7-position.

A2.2) Preference is likewise given to structures in accordance with DE-A-19846766, which are shown below. These polymers contain structural units of the formula (F)

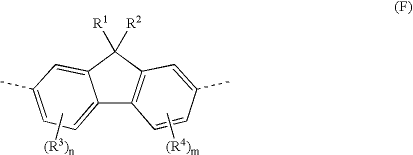

in which
R¹, R² represent two different substituents from the group C₅-C₄₀-aryl and C₂-C₄₀-heteroaryl, where the aryl and heteroaryl radicals mentioned above may be substituted by one or more substituents R³; for the purposes of this invention, the aryl and heteroaryl radicals are considered to be different if they differ through the type or position of substituents,
R³, R⁴ denote, identically or differently, C₁-C₂₂-alkyl, C₅-C₂₀-aryl or C₂-C₂₀-heteroaryl, F, Cl, CN, SO₃OR⁵ or NR⁵R⁶; the alkyl radicals here may be branched or unbranched or also represent cycloalkyls; and individual, non-adjacent CH₂ groups of the alkyl radical may be replaced by O, S, O═O, COO, N—R⁵ or also simple aryl radicals, where the aryl radicals mentioned above may be substituted by one or more non-aromatic substituents R³,
R⁵, R⁶ denote, identically or differently, H, C₁-C₂₂-alkyl or C₅-C₂₀-aryl or C₂-C₂₀-heteroaryl; the alkyl radicals here may be branched or unbranched or also represent cycloalkyls; and individual, non-adjacent CH₂ groups of the alkyl radical may be replaced by O, S, C═O, COO, N—R⁵ or also simple aryl radicals, where the aryl radicals mentioned above may be substituted by one or more non-aromatic substituents R³, and
m, n are, identically or differently, each an integer 0, 1, 2 or 3, preferably 0 or 1.

R¹, R² very particularly preferably stand for two different substituents from the group C₅-C₄₀-aryl, C₂-C₄₀-heteroaryl, where the aryl and heteroaryl radicals mentioned above may be substituted by one or more non-aromatic substituents R³.

A2.3) Preference is likewise given to structures in accordance with DE 19846768.0, which are shown below. These are polyfluorenes which, besides units of the formula (E1)

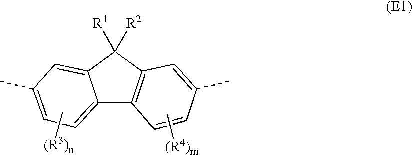

in which
R¹, R² denote, identically or differently, H, C₁-C₂₂-alkyl, C₅-C₂₀-aryl, C₂-C₂₀-heteroaryl, F, Cl or CN, where the alkyl radicals mentioned above may be branched or unbranched or also represent cyclo-alkyls, and individual, non-adjacent CH₂ groups of the alkyl radical may be replaced by O, S, C═O, COO, N—R⁵ or also simple aryl radicals, where the aryl radicals mentioned above may be substituted by one or more substituents R³. Preference is given to compounds in which R¹ and R² are both identical and are not equal to hydrogen or chlorine. Preference is furthermore given to compounds in which R¹ and R² are different from one another and are also different from hydrogen,
R³, R⁴ denote, identically or differently, C₁-C₂₂-alkyl, C₅-C₂₀-aryl, C₂-C₂₀-heteroaryl, F, Cl, CN, SO₃R⁵ or NR⁵R⁵; the alkyl radicals here may be branched or unbranched or also represent cyclo-alkyls; and individual, non-adjacent CH₂ groups of the alkyl radical may be replaced by O, S, C═O, COO, N—R⁵ or also simple aryl radicals, where the aryl radicals mentioned above may be substituted by one or more non-aromatic substituents R³,
R⁵, R⁶ denote, identically or differently, H, C₁-C₂₂-alkyl, or C₅-C₂₀-aryl; the alkyl radicals here may be branched or unbranched or also represent cycloalkyls; and individual, non-adjacent CH₂ groups of the alkyl radical may be replaced by O, S, C═O, COO, N—R⁵ or also simple aryl radicals, where the aryl radicals mentioned above may be substituted by one or more non-aromatic substituents R³, and
m, n are, identically or differently, each an integer 0, 1, 2 or 3, preferably 0 or 1,
   in each case also contain structural units of the formula (G1)

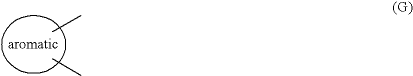

in which
“aromatic” is a mono- or polycyclic aromatic conjugated system having 5 to 20 carbon atoms, in which one or more carbon atoms may be replaced by nitrogen, oxygen or sulfur, and the linking points of which are selected in such a way that an angle not equal to 180°, preferably less than 120°, particularly preferably less than 90°, arises along the main polymer chain.

Particular preference is given here to polymers containing at least 1 mol %, preferably 2 mol % to 50 mol %, of structural units (one or more different) of structural unit (G).

The preparation of polymers of this type is described in detail in DE-A-19846767, DE-A-19846766 and DE-A-19846768. The preparation of corresponding polymers according to the invention can be carried out by copolymerisation of corresponding monomers which carry the substituents of the formula (A) and/or of the formula (I), (II) and/or (III).

A3) The homo- and copolymers of polyspiro contain one or more structural units of the formula (H), where at least one H atom in the polymer has been replaced by a substituent of the formula (A) and/or of the formula (I), (II) and/or (III)

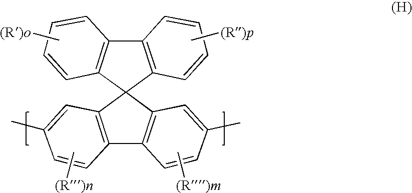

The substituents R′ to R″″ here are, identically or differently, H, CN, F, Cl or a straight-chain, branched or cyclic alkyl or alkoxy group having 1 to 20 C atoms, where one or more non-adjacent CH₂ groups may be replaced by —O—, —S—, —CO—, —COO—, —O—CO—, —NR¹—, —(NR²R³)⁺-A⁻ or —CONR⁴—, and where one or more H atoms may be replaced by F, or an aryl group having 4 to 40 C atoms, which may be substituted by one or more non-aromatic radicals,
R¹, R²,
R³, R⁴ are, identically or differently, aliphatic or aromatic hydrocarbon radicals having 1 to 20 C atoms or also H,
A⁻ is a singly charged anion or an equivalent thereof,
n, m, o, p are, identically or differently, 0, 1, 2 or 3, preferably 0, 1 or 2.

Preferred embodiments of the polyspiro are present in U.S. Pat. No. 5,621,131.

The preparation of polymers of this type is described in detail in U.S. Pat. No. 5,621,131. The preparation of corresponding polymers according to the invention can be carried out by copolymerisation of corresponding monomers which carry the substituents of the formula (A) and/or of the formula (I), (II) and/or (III).

A4) The homo- and copolymers of polydihydrophenanthrene contain one or more structural units of the formula (I), where at least one H atom in the polymer has been replaced by a substituent of the formula (A) and/or of the formula (I), (II) and/or (III)

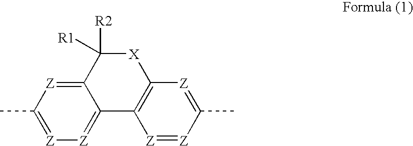

where the symbols used have the following meaning:
X is on each occurrence, identically or differently, C(R³)(R⁴) or N(R³)
Z is on each occurrence, identically or differently, C(R⁵) or N,
R¹, R²,
R³, R⁴ is on each occurrence, identically or differently, H, with the proviso that all substituents R¹ to R⁴ do not simultaneously describe H, a straight-chain, branched or cyclic alkyl or alkoxy chain having 1 to 22 C atoms, in which, in addition, one or more non-adjacent C atoms may be replaced by N—R⁶, O, S or O—CO—O, where, in addition, one or more H atoms may be replaced by fluorine, an aryl or aryloxy group having 5 to 40 C atoms, in which, in addition, one or more C atoms may be replaced by O, S or N and which may also be substituted by one or more non-aromatic radicals R¹, where, in addition, two or more of the radicals R¹ to R⁴ may form a ring system with one another; with the proviso that two substituents on a C atom (i.e. R¹ and R² or R³ and R⁴) do not simultaneously correspond to an alkoxy or aryloxy side chain and that all substituents R¹ to R⁴ do not simultaneously describe a methyl group, or fluorine, chlorine, bromine, iodine, CN, N(R⁶)₂, Si(R⁶)₃ or B(R⁶)₂,
R⁵ is on each occurrence, identically or differently, H, a straight-chain, branched or cyclic alkyl or alkoxy chain having 1 to 22 C atoms, in which, in addition, one or more non-adjacent C atoms may be replaced by O, S, —CO—O— or O—CO—O, where, in addition, one or more H atoms may be replaced by fluorine, an aryl or aryloxy group having 5 to 40 C atoms, in which, in addition, one or more C atoms may be replaced by O, S or N and which may also be substituted by one or more non-aromatic radicals R⁵, or F, CN, N(R⁶)₂ or B(R⁶)₂,
R⁶ is on each occurrence, identically or differently, H, a straight-chain, branched or cyclic alkyl chain having 1 to 22 C atoms, in which, in addition, one or more non-adjacent C atoms may be replaced by O, S, —CO—O— or O—CO—O, where, in addition, one or more H atoms may be replaced by fluorine, an aryl group having 5 to 40 C atoms, in which, in addition, one or more C atoms may be replaced by O, S or N and which may also be substituted by one or more non-aromatic radicals R¹.

Preferred embodiments of the polydihydrophenanthrenes are mentioned in WO 05/014689.

The preparation of polymers of this type is described in detail in WO 05/014689. The preparation of corresponding polymers according to the invention can be carried out by copolymerisation of corresponding monomers which carry the substituents of the formula (A) and/or of the formula (I), (II) and/or (III).

A5) The homo- and copolymers of polyphenanthrene contain one or more structural units of the formula (J), where at least one H atom in the polymer has been replaced by a substituent of the formula (A) and/or of the formula (I), (II) and/or (III)

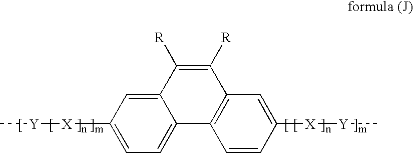

where the symbols and indices used have the following meaning:
R is on each occurrence, identically or differently, H, a straight-chain, branched or cyclic alkyl chain having 1 to 40 C atoms, which may be substituted by R¹ and in which one or more non-adjacent C atoms may be replaced by N—R¹, O, S, O—CO—O, CO—O, —CR¹═CR¹— or —C≡C—, with the proviso that the heteroatoms are not bonded directly to the phenanthrene unit, and in which, in addition, one or more H atoms may be replaced by F, Cl, Br, I or CN, or an aromatic or heteroaromatic ring system having 2 to 40 C atoms, which may also be substituted by one or more radicals R¹; the two radicals R here may also form a further mono- or polycyclic, aromatic or aliphatic ring system with one another; with the proviso that at least one of the two radicals R is not equal to H,
X is on each occurrence, identically or differently, —CR¹═CR¹—, —C≡C— or N—Ar,
Y is on each occurrence, identically or differently, a divalent aromatic or heteroaromatic ring system having 2 to 40 C atoms, which may be substituted by one or more radicals R¹ or unsubstituted,
R¹ is on each occurrence, identically or differently, H, a straight-chain, branched or cyclic alkyl or alkoxy chain having 1 to 22 C atoms, in which, in addition, one or more non-adjacent C atoms may be replaced by N—R², O, S, O—CO—O, CO—O, —CR¹═CR¹— or —C≡C— and in which, in addition, one or more H atoms may be replaced by F, Cl, Br, I or CN, or an aryl, heteroaryl, aryloxy or heteroaryloxy group having 5 to 40 C atoms, which may also be substituted by one or more non-aromatic radicals R¹; two or more of the radicals R¹ here may also form a ring system with one another and/or with R¹; or F, Cl, Br, I, CN, N(R²)₂, Si(R²)₃ or B(R²)₂,
R² is on each occurrence, identically or differently, H or an aliphatic or aromatic hydrocarbon radical having 1 to 20 C atoms,
Ar is on each occurrence, identically or differently, a monovalent aromatic or heteroaromatic ring system having 2 to 40 C atoms, which may be substituted by R¹ or unsubstituted,
n is on each occurrence, identically or differently, 0 or 1,
m is on each occurrence, identically or differently 0, 1 or 2,
   the dashed bond in formula (J) and in all other formulae denotes the link in the polymer; it is not intended to represent a methyl group here.

Preferred embodiments of the polyphenanthrenes are mentioned in DE 102004020298.

The preparation of polymers of this type is described in detail in DE 102004020298. The preparation of corresponding polymers according to the invention can be carried out by copolymerisation of corresponding monomers which carry the substituents of the formula (A) and/or of the formula (I), (II) and/or (II).

B) The low-molecular-weight compounds having a 3-dimensional spirobifluorene structure preferably consist of structural units of the formula (K1)

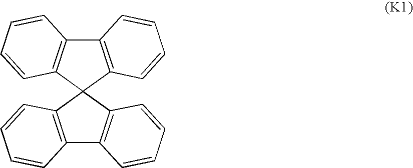

where the benzo groups may be substituted and/or fused independently of one another and where at least one H atom has been replaced by a substituent of the formula (A) and/or of the formula (I), (II) and/or (III).

Particular preference is given to compounds which are mentioned in EP-A-0676461 and are reproduced by the formula (K2)

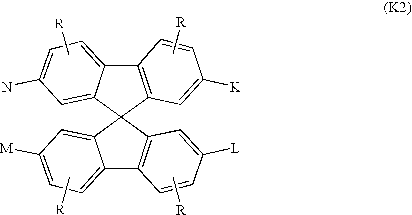

where the symbols and indices have the following meanings:
K, L, M, N are, identically or differently,

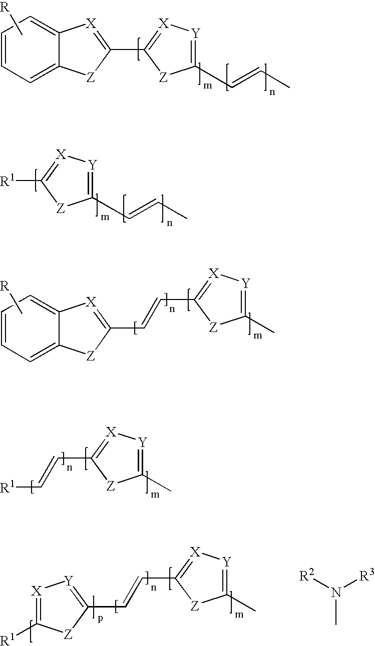

R can, identically or differently, have the same meanings as K, L, M, N or is —H, a linear or branched alkyl, alkoxy or ester group having 1 to 22 C atoms, —CN, —NO₂, —NR²R³, —Ar or —O—Ar,
Ar is phenyl, biphenyl, 1-naphthyl, 2-naphthyl, 2-thienyl, 2-furanyl, where each of these groups may carry one or two radicals R,
m, n, p are, identically or differently, 0, 1, 2 or 3,
X, Y are, identically or differently, CR or N,
Z is —O—, —S—, —NR¹—, —CR¹R⁴—, —CH═CH— or —CH═N—,
R¹, R⁴ can, identically or differently, have the same meanings as R,
R², R³ are, identically or differently, H, a linear or branched alkyl group having 1 to 22 C atoms, —Ar or 3-methylphenyl.

The preparation of compounds of this type is described in detail in EP 676461. The preparation of corresponding compounds according to the invention can be carried out by replacement of corresponding substituents or H atoms by the substituents of the formula (A) and/or of the formula (I), (II) and/or (III).

C) The low-molecular-weight compounds having a 3-dimensional triptycene structure preferably consist of structural units of the formula (L)

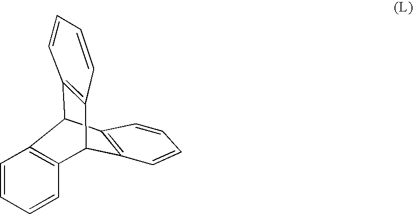

where the benzo groups may be substituted and/or fused independently of one another and where at least one H atom has been replaced by a substituent of the formula (A) and/or of the formula (I), (II) and/or (III).

Particular preference is given to the use of the compounds mentioned in DE-A-19744792.

The preparation of compounds of this type is described in detail in DE-A-19744792. The preparation of corresponding compounds according to the invention can be carried out by replacement of corresponding substituents or H atoms by the substituents of the formula (A) and/or of the formula (I), (II) and/or (III).

D) The low-molecular-weight compounds having a 2-dimensional triphenylene structure preferably consist of structural units of the formula (M)

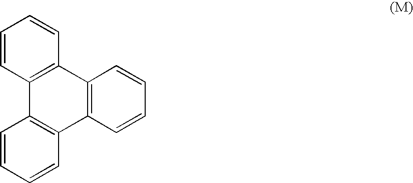

where the benzo groups may be substituted and/or fused independently of one another and where at least one H atom has been replaced by a substituent of the formula (A) and/or of the formula (I), (II) and/or (III).

Particular preference is given here to the use of the compounds mentioned in DE-A-4422332.

The preparation of compounds of this type is described in detail in DE-A-4422332. The preparation of corresponding compounds according to the invention can be carried out by replacement of corresponding substituents or H atoms by the substituents of the formula (A) and/or of the formula (I), (II) and/or (III).

E) The derivatives of perylenetetracarboxylic acid diimide preferably consist of structural units of the formula (N)

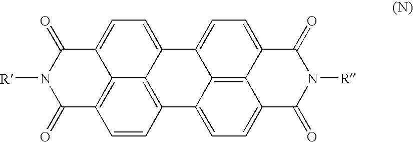

where the benzo groups may be substituted independently of one another and where at least one H atom has been replaced by a substituent of the formula (A) and/or of the formula (I), (II) and/or (III).

These substituents can denote, analogously to R′, R″, identically or differently, a straight-chain, branched or cyclic alkyl or alkoxy group having 1 to 20 C atoms, where one or more non-adjacent CH₂ groups may be replaced by —O—, —S—, —CO—, —COO—, —O—CO—, —NR¹—, —(NR²R³)⁺-A⁻ or —CONR⁴—, and where one or more H atoms may be replaced by F, or an aryl group having 4 to 14 C atoms, which may be substituted by one or more non-aromatic radicals R′. Furthermore, the substituents which are different from R′ and R″ may also denote CN, F or Cl.

The preparation of corresponding compounds according to the invention can be carried out by replacement of corresponding substituents or H atoms by the substituents of the formula (A) and/or of the formula (I), (II) and/or (III).

F) The derivatives of quinacridone preferably have structural units of the formula (O)

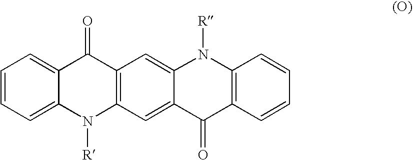

where the benzo groups may be substituted independently of one another and where at least one H atom has been replaced by a substituent of the formula (A) and/or of the formula (I), (II) and/or (III).

The substituents can denote, analogously to R′, R″, identically or differently, a straight-chain, branched or cyclic alkyl or alkoxy group having 1 to 20 C atoms, where one or more non-adjacent CH₂ groups may be replaced by —O—, —S—, —CO—, —COO—, —O—CO—, —NR¹—, —(NR²R³)⁺-A⁻ or —CONR⁴—, and where one or more H atoms may be replaced by F, or an aryl group having 4 to 14 C atoms, which may be substituted by one or more non-aromatic radicals R′. Furthermore, the substituents which are different from R′ and R″ may also denote CN, F or Cl.

The preparation of corresponding compounds according to the invention can be carried out by replacement of corresponding substituents or H atoms by the substituents of the formula (A) and/or of the formula (I), (II) and/or (III).

G) The organic lanthanoid complexes preferably consist of structural units of the formula (P)

LnR′ₙ (P)

The substituents R′ may be, identically or differently, carboxylates, ketonates, 1,3-diketonates, imides, amides or alcoholates, where at least one H atom has been replaced by a substituent of the formula (A) and/or of the formula (I), (II) and/or (III).

The number of ligands depends on the particular metal. Preference is given here to the organic complexes of europium, gadolinium and terbium, particularly preferably those of europium.

The preparation of corresponding compounds according to the invention can be carried out by replacement of corresponding substituents or H atoms in the substituents by the substituents of the formula (A) and/or of the formula (I), (II) and/or (III).

H) The derivatives of the metal quinoxalinate preferably consist of structural units of the formula (Q)

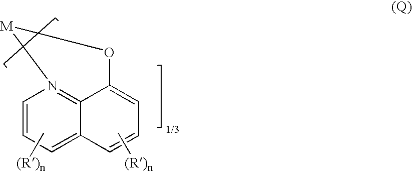

where the benzo groups may be substituted, independently of one another, by radicals R′.

M stands for aluminium, zinc, gallium or indium, preferably aluminium; n stands for an integer 0, 1, 2 or 3.

The substituents of the benzo group R′ can be, identically or differently, a straight-chain, branched or cyclic alkyl or alkoxy group having 1 to 20 C atoms, where one or more non-adjacent CH₂ groups may be replaced by —O—, —S—, —CO, —COO—, —O—CO—, —NR¹—, —(NR²R³)⁺-A⁻ or —CONR⁴—, and where one or more H atoms may be replaced by F, or an aryl group having 4 to 14 C atoms, which may be substituted by one or more non-aromatic radicals R′. Furthermore, the substituents which are different from R′ and R″ may also denote CN, F or Cl.

The substituents of the formula (A) and/or of the formula (I), (II) and/or (III) can either replace an H atom on one of the quinoxaline rings or also sit on another ligand R′ which replaces one of the quinoxaline ligands.

I) The derivatives of oxadiazole preferably consist of structural units of the formula (R)

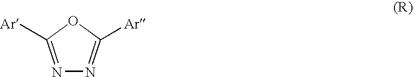

where Ar′ and Ar″ can be, identically or differently, a substituted or unsubstituted aromatic or heteroaromatic radical having 4 to 14 C atoms, where at least one H atom has been replaced by a substituent of the formula (A) and/or of the formula (I), (II) and/or (III).

Ar′ and Ar″ are particularly preferably, identically or differently, phenyl, 1- or 2-naphthyl, 1-, 2- or 9-anthracenyl, 2-, 3- or 4-pyridinyl, 2-, 4- or 5-pyrimidinyl, 2-pyrazinyl, 3- or 4-pyridazinyl, 2-, 3-, 4-, 5-, 6-, 7- or 8-quinoline, 2- or 3-thiophenyl, 2- or 3-pyrrolyl or 2- or 3-furanyl.

The possible substituents are, identically or differently, CN, F, Cl, CF₃ or a straight-chain, cyclic or branched alkyl or alkoxy group having 1 to 12 C atoms, where one or more non-adjacent CH₂ groups may be replaced by —O—, —S—, —CO—, —COO—, —O—CO—, —NR¹—, —(NR²R³)⁺-A⁻ or —CONR⁴—, and where one or more H atoms may be replaced by F.

The substituents of the formula (A) and/or of the formula (I), (II) and/or (III) can either replace an H atom on one of the aryl rings or also sit on one of the substituents of the aryl rings.

J) Organometallic complexes which are capable of phosphorescence are distinguished by emission from the triplet state. Suitable materials are described, for example, in M. A. Baldo et al, Appl. Phys. Lett. 1999, 75, 4-6 and WO 02/068435, WO 04/026886 and WO 03/000661. Further organometallic complexes which are capable of phosphorescence contain compounds of the formula (T)

[M(L)ₙ(L′)ₘ(L″)ₒ] (T)

containing a sub-structure M(L)ₙ of the formula (U)

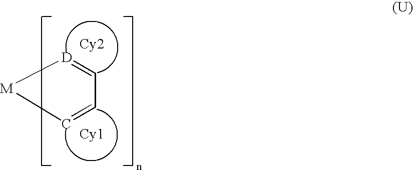

where the following applies to the symbols and indices used:
M is on each occurrence an element from the first to ninth sub-groups of the Periodic Table of the Elements, preferably iridium, rhodium, platinum, palladium, gold, tungsten, rhenium, ruthenium or osmium,
D is, identically or differently on each occurrence, an sp²-hybridised heteroatom having a non-bonding electron pair which coordinates to M,
C is on each occurrence an sp²-hybridised carbon atom which bonds to M,
Cy1 is, identically or differently on each occurrence, a homo- or heterocycle which is optionally substituted by R and bonds to M via an sp²-hybridised carbon atom; Cy1 here can be either a monocycle or an oligocycle,
Cy2 is, identically or differently on each occurrence, a heterocycle which is optionally substituted by R and coordinates to M via the atom D; Cy2 here can be either a monocycle or an oligocycle,
R is, identically or differently on each occurrence, H, deuterium, F, CN, a straight-chain alkyl or alkoxy group having 1 to 40 C atoms, a branched or cyclic alkyl or alkoxy group having 3 to 40 C atoms, where one or more non-adjacent CH₂ groups in the above-mentioned alkyl or alkoxy groups may each be replaced by —R²C═CR²—, —C≡C—, Si(R²)₂, Ge(R²)₂, Sn(R²)₂, —O—, —S—, —NR²—, —(C═O)—, —(C═NR²)—, —P═O(R²)— or —CONR²— and where one or more H atoms may be replaced by F,
   or
   an aromatic system having 6 to 30 C atoms, a heteroaromatic system having 2 to 30 C atoms or an aryloxy or heteroaryloxy group of the above-mentioned systems, each of which may be substituted by one or more radicals R¹; two or more radicals R here, on the same ring or on different rings, may also form a further aliphatic or aromatic ring system with one another,
R¹ is, identically or differently on each occurrence, H, deuterium, F, Cl, Br, I, OH, NO₂, CN, N(R²)₂, a straight-chain alkyl or alkoxy group having 1 to 40 C atoms, a branched or cyclic alkyl or alkoxy group having 3 to 40 C atoms, where one or more non-adjacent CH₂ groups in the above-mentioned alkyl or alkoxy groups may each be replaced by —R²C═CR²—, —C≡C—, Si(R²)₂, Ge(R²)₂, Sn(R²)₂, —O—, —S—, —NR²—, —(C═O)—, —(C═NR¹, —P═O(R²)—, —COOR²— or —CONR²— and where one or more H atoms may be replaced by F,
   or
   an aromatic system having 6 to 30 C atoms, a heteroaromatic system having 2 to 30 C atoms or an aryloxy or heteroaryloxy group of the above-mentioned systems, each of which may be substituted by one or more non-aromatic radicals R¹, where a plurality of substituents R¹, both on the same ring and also on different rings, may together in turn form a further mono- or polycyclic, aliphatic or aromatic ring system,
R² is, identically or differently on each occurrence, H or an aliphatic hydrocarbon radical having 1 to 20 C atoms or an aromatic hydrocarbon radical having 6 to 20 C atoms or a heteroaromatic hydrocarbon radical having 2 to 30 C atoms,
   the ligands L′ and L″ in formula (T) are bidentate chelating ligands, m and are, identically or differently on each occurrence, 0, 1 or 2.

n+m+o=2 here for metals with square-planar coordination, for example platinum and palladium, and n+m+o=3 for metals with octahedral coordination, for example iridium.

Furthermore, the ring Cy2 may also be a carbene which coordinates to the metal, as described, for example, in WO 05/019373.

K) Polymers (polystyrenes) which carry tetraarylbenzidine units in the side chain consist of structural units of the formula (S) or analogous compounds in the case of other polymer backbones (polyacrylates, polyamides, polyesters)

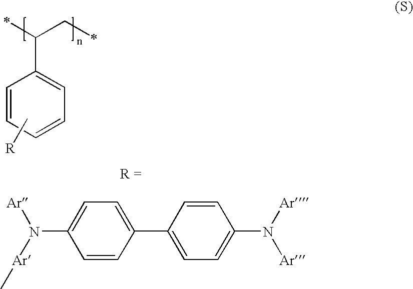

where Ar′, A″, Ar′″ and Ar″″ can be, identically or differently, a substituted or unsubstituted aromatic or heteroaromatic radical having 4 to 14 C atoms.

Ar′, Ar″, Ar′″ and Ar″″ are preferably, identically or differently, phenyl, 1- or 2-naphthyl, 1-, 2- or 9-anthracenyl, 2-, 3- or 4-pyridinyl, 2-, 4- or 5-pyrimidinyl, 2-pyrazinyl, 3- or 4-pyridazinyl, 2-, 3-, 4-, 5-, 6-, 7- or 8-quinoline, 2- or 3-thiophenyl, 2- or 3-pyrrolyl or 2- or 3-furanyl.

The possible substituents are, identically or differently, CN, F, Cl, CF₃ or a straight-chain, cyclic or branched alkyl or alkoxy group having 1 to 12 C atoms, where one or more non-adjacent CH₂ groups may be replaced by —O—, —S—, —CO—, —COO—, —O—CO—, —NR¹—, —(NR²R³)⁺-A⁻ or —CONR⁴— and where one or more H atoms may be replaced by F.

This tetraarylbenzidine group is bonded to the main polymer chain via a spacer, preferably a C1 to C6 alkyl, alkoxy or ester group.

The substituents of the formula (A) and/or of the formula (I), (II) and/or (III) can either replace an H atom on one of the aryl rings or sit on one of the substituents of the aryl rings, or also on another copolymerised monomer which does not carry a tetraarylbenzidine unit.

The substances outlined above can be used as the pure substance or also in a mixture with one another or also with other assistants.

The other components of layer B which do not participate in the chemical reaction for the purposes of the invention are electroluminescent or laser materials, preferably
A) homo- or copolymers based on PPV or polyfluorenes or polyspiro or polydihydrophenanthrene or polyphenanthrene or polyindenofluorene,
B) low-molecular-weight compounds having a 3-dimensional spirobifluorene structure,
C) low-molecular-weight compounds having a 3-dimensional triptycene structure,
D) low-molecular-weight compounds having a 2-dimensional triphenylene structure,
E) derivatives of perylenetetracarboxylic acid diimide,
F) derivatives of quinacridone,
G) organic lanthanoid complexes,
H) derivatives of aluminium trisquinoxalinate,
I) oxadiazole and triazine derivatives,
J) organometallic complexes which are capable of phosphorescence,
   hole-conductor materials, preferably
K) polystyrenes, polyacrylates, polyamides, polyesters, which carry derivatives of tetraarylbenzidine in the side chain,
L) low-molecular-weight compounds having a 2-dimensional triphenylene and triarylamine structure,
   or electron-conductor materials, preferably
M) derivatives of aluminium trisquinoxalinate,
N) oxadiazole and triazine derivatives,
O) derivatives of diphenyl ketone, as described, for example, in WO 2005/040302 A1.

However, it is also possible to employ unreactive materials, which produce a non-conducting layer B2 on layer B1 or do not have any fluorescent properties.

Furthermore, the components which form layer B2 and further layers forming on B1 are not restricted to organic or organic-semiconducting materials.

It is particularly preferred for the composition of the organic semiconducting layer to consist of at least two components, one of which is capable of chemical reaction.

However, there is no restriction regarding the number of components. Thus, the composition of layer B can also consist of three or more organic or inorganic materials, two of which are capable of chemical reactions and directional separation, so long as these chemical reactions are of different natures and/or of the same nature, but proceed at significantly different rates. This makes it possible, in a further embodiment, to obtain multilayered elements. It is likewise possible to repeat the procedure in order to obtain more complex layer structures.

If the chemical reactions are of different natures, it is crucial that the initiation of the chemical reaction takes place in different ways. Initiation methods can be, independently of one another, of a thermal, photochemical or ionic nature or with the aid of a photoacid. A photoacid is a compound which liberates a protic acid due to photochemical reaction on irradiation with actinic radiation. Examples of photoacids are 4-(thio-phenoxyphenyl)diphenylsulfonium hexafluoroantimonate, {4-[(2-hydroxytetradecyl)oxy]-phenyl}phenyliodonium hexafluoroantimonate and others, as described, for example, in EP 1308781. The photoacid can be added for the crosslinking reaction, in which case a proportion of about 0.5 to 3% by weight is preferably selected, but does not necessarily have to be added. It is particularly preferred for one of the initiation methods to be of a thermal nature.

In the case of reactions of the same nature, but with different rates, it is particularly preferred for these to have a difference in the rate constants of more than one order of magnitude. It is very particularly preferred for this difference to be two or more orders of magnitude.

This procedure makes it possible, initiated by layer A, to achieve a layer structure in which layer B is separated into more than two layers.

For the purposes of this invention, electronic devices are organic or polymeric light-emitting diodes (OLEDs, PLEDs, for example EP 0 676 461, WO 98/27136), organic solar cells (O-SCs, for example WO 98/48433, WO 94/05045), organic field-effect transistors (O-FET, for example U.S. Pat. No. 5,705,826, U.S. Pat. No. 5,596,208, WO 00/42668), organic thin-film transistors (O-TFTs), organic integrated circuits (O-ICs, for example WO 95/31833, WO 99/10939), organic field-quench devices (FQDs, for example US 2004/017148), organic optical amplifiers, organic light-emitting transistors (OLETs, for example WO 04/086526) and organic laser diodes (O-lasers, for example WO 98/03566). For the purposes of this invention, organic means that at least one layer of an organic conductive doped polymer or at least one conducting or semiconducting polymeric buffer layer or at least one layer comprising at least one organic semiconductor is present; further organic layers (for example electrodes, etc.) may also be present. However, it is also possible for layers which are not based on organic materials, such as, for example, further interlayers or electrodes, to be present.

In the simplest case, the electronic device is constructed from a substrate (usually glass or plastic film), an electrode, interlayers according to the invention and a counterelectrode. This device may be structured correspondingly (depending on the application), provided with contacts and finally hermetically sealed, since the lifetime of such devices in the presence of water and/or air may be drastically shortened. For applications in O-FETs and O-TFTs, it is also necessary for the structure, apart from the electrode and counterelectrode (source and drain), also to contain a further electrode (gate), which is separated from the organic semiconductor by an insulator layer, generally having a high (or more rarely low) dielectric constant. In addition, it may be appropriate to introduce further layers into the device.

The electrodes are selected so that their potential corresponds as well as possible to the potential of the adjacent organic layer in order to ensure the most efficient electron or hole injection possible. Preferred cathodes are metals having a low work function, metal alloys or multilayered structures comprising different metals, such as, for example, alkaline-earth metals, alkali metals, main-group metals or lanthanoids (for example Ca, Ba, Mg, Al, In, Mg, Yb, Sm, etc.). In the case of multilayered structures, further metals which have a relatively high work function, such as, for example, Ag, may also be used in addition to the said metals, in which case combinations of the metals, such as, for example, Ca/Ag or Ba/Ag, are then generally used.

It may also be preferred to introduce a thin interlayer of a material having a high dielectric constant between a metallic cathode and the organic semiconductor. Suitable for this purpose are, for example, alkali-metal or alkaline-earth metal fluorides, but also corresponding oxides (for example LiF, Li₂O, BaF₂, MgO, NaF, etc.). The layer thickness of this dielectric layer is preferably between 1 and 10 nm.

Preferred anodes are materials having a high work function. The anode preferably has a potential of greater than 4.5 eV against vacuum. Suitable for this purpose are on the one hand metals having a high redox potential, such as, for example, Ag, Pt or Au. Metal/metal oxide electrodes (for example Al/Ni/NiOₓ, Al/Pt/PtOₓ) may also be preferred.

For some applications, at least one of the electrodes must be transparent in order to facilitate either irradiation of the organic material (O-SC) or the coupling-out of light (OLED/PLED, O-LASERS). A preferred structure uses a transparent anode. Preferred anode materials here are conductive mixed metal oxides. Particular preference is given to indium tin oxide (ITO) or indium zinc oxide (IZO). Preference is furthermore given to conductive, doped organic materials, in particular conductive doped polymers.

The organic semiconductor layer B can preferably be applied by various printing processes, in particular by ink-jet printing processes. For the purposes of this invention, an organic material is intended to be taken to mean not only purely organic compounds, but also organometallic compounds and metal coordination compounds with organic ligands. In the case of luminescent compounds, these may either fluoresce or phosphoresce, i.e. emit light from the singlet state or from the triplet state. The polymeric materials here may be conjugated, partially conjugated or non-conjugated. Preference is given to conjugated materials. For the purposes of this invention, conjugated polymers are polymers which contain principally sp²-hybridised carbon atoms, which may also be replaced by corresponding heteroatoms, in the main chain. Furthermore, this application text likewise uses the term conjugated if, for example, arylamine units and/or certain heterocycles (i.e. conjugation via N, O or S atoms) and/or organometallic complexes (i.e. conjugation via the metal atom) are located in the main chain. Typical representatives of conjugated polymers, as can be used, for example, in PLEDs or O-SCs, are poly-para-phenylenevinylenes (PPVs), polyfluorenes, polyspirobifluorenes, polydihydrophenanthrenes, polyphenanthrenes, polyindenofluorenes, systems based in the broadest sense on poly-p-phenylenes (PPPs), and derivatives of these structures. For use in O-FETs, materials having high charge-carrier mobility are of particular interest. These are, for example, oligo- or poly(triarylamines), oligo- or poly(thiophenes) and copolymers which contain a high proportion of these units.

The layer thickness of the organic semiconductor, depending on the application, is preferably 10 to 500 nm, particularly preferably 20 to 250 nm.

Depending on the composition of the layer of the organic semiconductor, the directional separation enables any desired ratio of the separated layers to one another to be established. The layer thicknesses actually established of the separated layers depend on the function of the layer in the organic electronic device. The establishment of the desired layer thickness of the separated layers with respect to one another is determined by the ratio of the reactive materials to the unreactive materials in mixture B before the directional separation.

The present invention furthermore relates to the use of directional separation of the organic semiconductor layer for the production of films having a homogeneous surface profile.

If soluble polymeric systems are applied to a substrate by a printing process, preferably ink-et printing, evaporation of the solvent results in directional transport of dissolved material to the droplet edge with formation of an inhomogeneous layer thickness, where the layer thickness at the edge of the droplet is greater than in the centre.

If layers according to the invention are brought to directional separation of the components of the layer by chemical reaction, preferably thermally initiated cationic polymerisation, a very homogeneous layer-thickness distribution of the crosslinked layer forms, irrespective of how homogeneous or inhomogeneous the surface of the layer as a whole is. By dissolution of the uncrosslinked layer, a layer which has only a slight variation in the layer thickness can be obtained in this way.

It is particularly preferred for these layer-thickness variations to be in the range between 0.1 and 3 nm, in particular in the range between 0.5 and 1 nm.

For the production of the preferred devices according to the invention, use is generally made of the following general process, which can be adapted correspondingly for the individual case without further inventive step:
A substrate (for example glass or also a plastic) is coated with the anode (for example indium tin oxide, ITO). The anode is subsequently structured (for example photolithographically) in accordance with the desired application and provided with connections. The pre-cleaned substrate coated with the anode is treated with ozone or with oxygen plasma or briefly irradiated using an excimer lamp.
A conductive polymer, for example a doped polythiophene (PEDOT) or polyaniline (PANI) derivative, is subsequently applied in a thin layer A to the ITO substrate by spin coating or other coating methods.
Layer B according to the invention is applied to this layer. For this purpose, the corresponding mixture is firstly dissolved in a solvent or solvent mixture, preferably under protective gas, and filtered. Suitable solvents are aromatic liquids (for example toluene, xylenes, anisole, chlorobenzene), cyclic ethers (for example dioxane, methyldioxane, THF) or amides (for example NMP, DMF), but also solvent mixtures, as described, for example, in WO 02/072714. The supports described above can be coated with these solutions over the entire surface, for example by spin-coating methods, or in a structured manner by printing processes, in particular ink-jet printing. The directional separation can then be carried out (on use of cationically crosslinkable groups) by heating the device in an inert atmosphere at this stage. Depending on the type of crosslinkable group, the crosslinking can be initiated in various ways. Rinsing with a solvent, for example THF, can optionally then be carried out. This then removes the newly formed layer B2 again in order to obtain surface profiles of layer B1 with few layer-thickness variations. In general, this rinsing step is omitted, and layer structure A-B1-B2 is obtained. Finally, the structure is dried.
Further functional layers, such as, for example, charge-injection or -transport layers or hole-blocking layers, can optionally be applied to these polymer layers, for example from solution, but also by vapour deposition.
A cathode is subsequently applied. This is carried out in accordance with the prior art by a vacuum process and can take place, for example, either by thermal vapour deposition or by plasma spraying (sputtering).
Since many of the applications are sensitive to water, oxygen or other constituents of the atmosphere, effective encapsulation of the device is vital.
The structure described above will be correspondingly adapted and optimised for the individual applications without further inventive step and can generally be used for various applications, such as, for example, organic and polymeric light-emitting diodes, organic solar cells, organic field-effect transistors, organic thin-film transistors, organic integrated circuits, organic optical amplifiers or organic laser diodes.

Surprisingly, the production of organic electronic devices with the aid of the directional separation according to the invention offers the following advantages:
1) In the case where a crosslinked organic buffer layer is formed by the directional separation, the opto-electronic properties of the electronic device are improved compared with a device in which only a material blend which does not separate in a directional manner or a one-component system is used for the production of this layer. Thus, higher efficiency and a longer lifetime are observed.
2) The directional separation gives rise to a considerable technical advance since a multilayered structure can be applied in just one area-coating step and comparable opto-electronic properties are achieved, which relates to the efficiency, colour and lifetime of the organic electro-optical device.
3) The formation of a crosslinked buffer layer and the establishment of any desired layer thickness through mixing ratios enables thicker buffer layers to be produced than is possible with uncrosslinked buffer layers, which only form a thin, insoluble layer through conditioning and rinsing. These thicker, crosslinked buffer layers give rise to better device results than uncrosslinked, thinner buffer layers in accordance with the prior art.
4) The cationic crosslinking of layer B1 removes the reliance on a low glass transition temperature and thus on a low-molecular-weight material for the conditioning. The fact that high-molecular-weight materials can now also be used for this purpose enables layer B1 to be applied by ink-jet printing.
5) On use of light-emitting components which can be directionally separated in layer B, it is possible to obtain coloured multilayered systems having better properties than can be achieved by means of blends. This is evident in higher efficiencies and longer lifetimes.
6) The directional crosslinking emanating from layer A enables layers having very few layer-thickness variations to be obtained by printing processes, which is impossible in accordance with the prior art, if the uncrosslinked layer is washed off.
7) The chemically induced, directional phase separation enables very homogeneous interfaces to be obtained, which results in reduced formation of black spots or similar defects.

The present invention is explained in greater detail by the following examples, without wishing it to be restricted thereto. In these examples, only organic and polymeric light-emitting diodes are discussed. However, the person skilled in the art will be able to use the examples given to produce, without an inventive step, further electronic devices, such as, for example, O-SCs, O-FETs, O-TFTs, O-LETs, O-FQDs, O-ICs, organic optical amplifiers and O-lasers, to mention but a few further applications.

### EXAMPLE 1

### General Procedure

The invention is described by way of example through the use of polymer 1, as described below (WO 2005/024971A1), and a blue polymer of the formula 2.

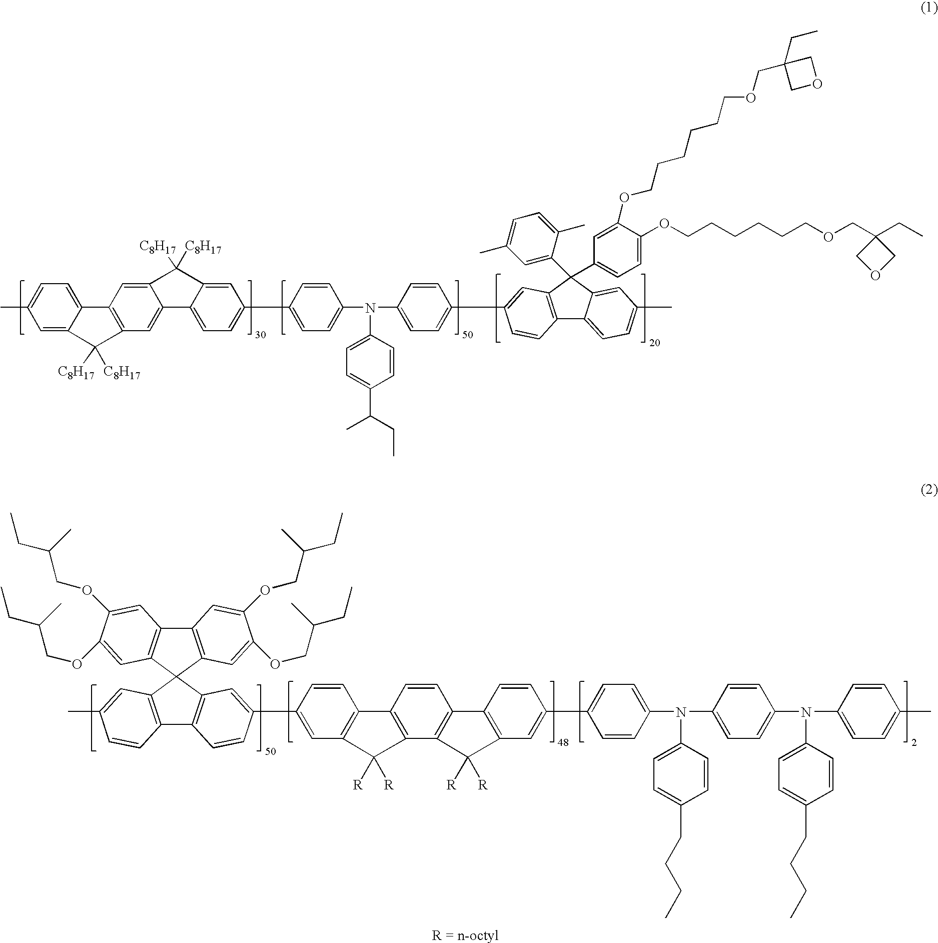

The working steps to be carried out are as follows:
1) PEDOT/PSSH, obtainable from HC Starck as Baytron® P 4083, is spin-coated in a layer thickness of about 80 nm onto a glass substrate which is coated with ITO (indium tin oxide) (layer A).
2) Polymers 1 and 2 are dissolved in toluene in the ratio 20/65. The concentration established in this mixture is 12 mg/ml.
3) The toluene solution of the mixture of 1 and 2 is spin-coated in a layer thickness of 85 nm onto the PEDOT-coated substrate (layer B).
4) The substrate is conditioned at 150° C. for 2 hours.
5) The substrate can now optionally be rinsed with THF. A check of the total layer thickness gives 105 nm (80 nm of PEDOT+20 nm of crosslinked material 1), which confirms that the crosslinkable component 1 has become insoluble. The soluble component 2 can be removed by rinsing with THF.
6) In the case where a rinsing step is not carried out, a cathode comprising Ba is now applied by vapour deposition in a layer thickness of 5.5 nm and a top electrode, consisting of Ag, is applied in a layer thickness of 150 nm.
7) Air-tight encapsulation of the device by means of a glass cover and a UV-active adhesive XA 80226 from Emerson&Cuming®.

The resultant device exhibits the following characteristic data:

| | |
|---|---|
| Max. efficiency | 5.35 cd/A |
| Colour: | x 0.20 y 0.29 |
| Lifetime: | 108 hours at an initial luminous density of 400 cd/m² |

### COMPARATIVE EXAMPLE 1

A device is produced analogously to working steps 1, 2, 3, 4, 6 and 7 of Example 1. In working step 2, however, only polymer 2 is weighed out in the stated concentration and is applied by spin coating in working step 3 only in a layer thickness of 65 nm, which corresponds to the layer thickness of polymer 2 in layer B2 in Example 1. The resultant device exhibits the following characteristic data:

| | |
|---|---|
| Max. efficiency | 3.4 cd/A |
| Colour: | x 0.19 y 0.26 |
| Lifetime: | 35 hours at an initial luminous density of 400 cd/m² |

1-28. (canceled)

29. An electronic component comprising at least one anode, at least one cathode, at least one charge-injection layer, at least one layer of an organic semiconductor, and at least one layer located between said charge-injection layer and said organic semiconductor layer, wherein both said layer located between said charge-injection layer and said organic semiconductor layer and said organic semiconductor layer are obtained by coating said charge-injection layer with a mixture comprising at least one material which can be rendered insoluble via a chemical reaction and at least one organic semiconductor.

30. The electronic component of claim 29, wherein said chemical reaction is initiated by said charge-injection layer.

31. The electronic component of claim 29, wherein said chemical reaction produces complete and directional separation of the organic semiconductor.

32. The electronic component of claim 29, wherein said charge-injection layer comprises a material suitable for initiating a chemical reaction.

33. The electronic component of claim 29, wherein said reaction is initiated thermally.

34. The electronic component of claim 33, wherein said reaction is initiated at a temperature in the range of from 50 to 250° C.

35. The electronic component of claim 29, wherein said charge-injection layer comprises a conductive, polymeric material, wherein said conductive, polymeric material is optionally doped.

36. The electronic component of claim 29, wherein said electronic component comprises an inorganic or organic semiconducting and/or non-conducting layer instead of said charge-injection layer.

37. The electronic component of claim 29, wherein said charge-injection layer comprises polymers having a conductivity of 10⁻⁸ S/cm or greater.

38. The electronic component of claim 29, wherein said charge-injection layer has a layer thickness in the range of from 10 to 500 nm.

39. The electronic component of claim 38, wherein said charge-injection layer comprises polythiophene and derivatives thereof and/or polyaniline and derivatives thereof.

40. The electronic component of claim 39, wherein said polythiophene and derivatives thereof and/or said polyaniline and derivatives thereof are doped with acids or oxidants.

41. The electronic component of claim 29, wherein said mixture comprises soluble polymers, low-molecular-weight compounds, or mixtures thereof wherein at least two compounds of said soluble polymers, low-molecular-weight compounds, or mixtures thereof are different.

42. The electronic component of claim 29, wherein said chemical reaction results in directional separation of the layer.

43. The electronic component of claim 42, wherein said chemical reaction is a crosslinking reaction.

44. The electronic component of claim 43, wherein said crosslinking reaction is a polymerisation reaction that is anionically initiated, cationically initiated, free radically initiated, a metathesis reaction, or a Diels-Alder reaction.

45. The electronic component of claim 44, wherein said polymerisation reaction is a thermally initiated cationic polymerisation.

46. The electronic component of claim 43, wherein crosslinkable polymers are used in said crosslinking reaction.

47. The electronic component of claim 46, wherein said crosslinkable polymers have a molecular weight in the range of from 50 to 500 kg/mol.

48. The electronic component of claim 43, wherein the layer produced by said crosslinking reaction has a thickness of from 1 to 300 nm.

49. The electronic component of claim 43, wherein cationically crosslinkable materials based on triarylamine, thiophene, triarylphosphine, or combinations thereof or copolymers comprising triarylamine structures, thiophene structures, triarylphosphine structures, or combinations thereof are used in said crosslinking reaction.

50. The electronic component of claim 49, wherein said copolymers additionally comprise fluorene, spirobifluorene, dihydrophenanthrene, indenofluorene, and/or phenanthrene structures.

51. The electronic component of claim 43, wherein cationically crosslinkable groups selected from the group consisting of (i) electron-rich olefin derivatives, (ii) heteronuclear multiple bonds with heteroatoms or heterogroups, (iii) ring compounds containing heteroatoms and which react by cationic ring-opening polymerisation, and (iv) mixtures thereof are employed in said crosslinking reaction.

52. The electronic component of claim 43, wherein low-molecular-weight, oligomeric or polymeric organic materials wherein at least one H atom has been replaced by a group of formula (I), formula (II), and/or formula (III) 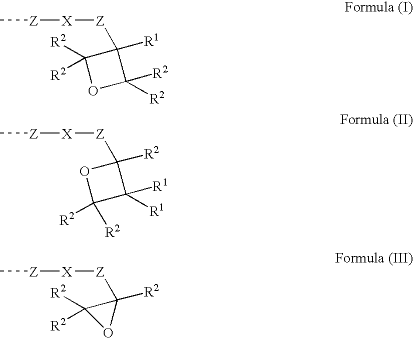
wherein
R¹ is, identically or differently on each occurrence, hydrogen; a straight-chain, branched, or cyclic alkyl, alkoxy, or thioalkoxy group having up to 20 C atoms; an aromatic or heteroaromatic ring system having 4 to 24 aromatic ring atoms; or an alkenyl group having 2 to 10 C atoms; wherein one or more hydrogen atoms are optionally replaced by halogen or CN and one or more non-adjacent C atoms are optionally replaced by —O—, —S—, —CO—, —COO—, or —O—CO—; and wherein a plurality of radicals R¹ optionally define a monocyclic or polycyclic, aliphatic or aromatic ring system with one another or with R², R³, and/or R⁴;
R² is, identically or differently on each occurrence, hydrogen; a straight-chain, branched, or cyclic alkyl group having up to 20 C atoms; an aromatic or heteroaromatic ring system having 4 to 24 aromatic ring atoms; or an alkenyl group having 2 to 1° C. atoms; wherein one or more hydrogen atoms are optionally replaced by halogen or CN and one or more non-adjacent C atoms are optionally replaced by —O—, —S—, —CO—, —COO—, or —O—CO—; and wherein a plurality of radicals R² optionally define a monocyclic or polycyclic, aliphatic or aromatic ring system with one another or with R¹, R³, and/or R⁴;
X is, identically or differently on each occurrence, —O—, —S—, —CO—, —COO—, —O—CO—, or a divalent group —(CR³R⁴)ₙ—;
Z is, identically or differently on each occurrence, a divalent group —(CR³R⁴)ₙ—;
R³ and R⁴
are, identically or differently on each occurrence, hydrogen; a straight-chain, branched, or cyclic alkyl, alkoxy, alkoxyalkyl, or thioalkoxy group having up to 20 C atoms; an aromatic or heteroaromatic ring system having 4 to 24 aromatic ring atoms; or an alkenyl group having 2 to 10 C atoms; wherein one or more hydrogen atoms are optionally replaced by halogen or CN; and wherein two or more radicals R³ or R⁴ optionally define a ring system with one another or also with R¹ or R²;
n is, identically or differently on each occurrence, an integer from 0 and 20; with the proviso that the number of said groups of formula (I), formula (II), and/or formula (III) is limited by the maximum number of available H atoms;
are employed in said crosslinking reaction.

53. The electronic component of claim 43, wherein an electroluminescent or laser material is employed in said crosslinking reaction.

54. The electronic component of claim 29, wherein said mixture comprises an unreactive component and/or said organic semiconductor layer comprises an electroluminescent and/or laser material.

55. The electronic component of claim 29, wherein said electronic component is an organic or polymeric light-emitting diode, an organic solar cell, an organic field-effect transistor, an organic thin-film transistor, an organic integrated circuit, an organic field-quench device, an organic optical amplifier, an organic light-emitting transistor, or an organic laser diode.

56. A process for producing an electronic component comprising at least one anode, at least one cathode, at least one charge-injection layer, at least one layer of an organic semiconductor, and at least one layer located between said charge-injection layer and said organic semiconductor layer comprising coating said charge-injection layer with a mixture comprising at least one material which can be rendered insoluble via a chemical reaction and at least one organic semiconductor.
